(19) United States
(12) Patent Application Publication
(10) Pub. No.: US 2026/0282830 A1
(43) Pub. Date: Sep. 17, 2026

(54) ELECTROSTATIC CHUCK

(71) Applicant: TOTO LTD., Fukuoka (JP)

(72) Inventors: Yohei UENO, Fukuoka (JP); Yuki OSAKABE, Fukuoka (JP); Masafumi IKEGUCHI, Fukuoka (JP); Tomoki UMETSU, Fukuoka (JP); Tatsuya MORI, Fukuoka (JP); Keigo UMEZAWA, Fukuoka (JP)

(73) Assignee: TOTO LTD., Fukuoka (JP)

(21) Appl. No.: 19/542,278

(22) Filed: Feb. 17, 2026

(30) Foreign Application Priority Data
Mar. 17, 2025 (JP) 2025-042203

(51) Int. Cl. H10P 72/72

(52) U.S. Cl. CPC H10P 72/722

(57) ABSTRACT

An electrostatic chuck 10 includes: a dielectric substrate 100 in which a first gas hole 141 is formed; a heater unit 300 that is joined to a surface 120 on a side opposite to a placement surface in the dielectric substrate 100 and has a second gas hole 302 formed at a position corresponding to the first gas hole 141; a base plate that is joined to a surface on a side opposite to the dielectric substrate 100 in the heater unit 300 and has a third gas hole 203 formed at a position corresponding to the second gas hole 302; and an air-permeable member 500 that is made of an insulator and has air permeability, the air-permeable member 500 being arranged so as to enter both an interior of the second gas hole 302 and an interior of the third gas hole 203.

### CROSS-REFERENCE TO RELATED APPLICATION

This application is based upon and claims the benefit of priority from Japanese Patent Application No. 2025-042203 filed on Mar. 17, 2025, the entire contents of which are incorporated herein by reference.

### FIELD

The present invention relates to an electrostatic chuck.

### BACKGROUND

For example, in a semiconductor manufacturing apparatus including an etching apparatus, an electrostatic chuck is provided as an apparatus configured to attract and hold a wafer such as a silicon wafer to be processed. The electrostatic chuck includes a dielectric substrate to which an attraction electrode is provided and a base plate which supports the dielectric substrate. When a voltage is applied to the attraction electrode, an electrostatic force is generated, and the wafer placed on the dielectric substrate is attracted and held.

During a process on the wafer, an in-plane temperature distribution of the wafer is required to be as uniform as possible. To enable the in-plane temperature distribution of the wafer to be regulated with high accuracy, an electrostatic chuck including a heater has been developed in recent years, which has already been put to practical use. The heater may be provided inside the dielectric substrate, or may be provided as a heater unit between the dielectric substrate and the base plate as disclosed in, for example, Japanese Patent Laid-open No. 2021-197485.

### SUMMARY

For purposes such as temperature regulation of the substrate during processing, inert gas such as helium is often supplied between the dielectric substrate and the substrate. As a supply path for such gas, a gas hole is formed in each of the dielectric substrate and the base plate. In a configuration in which a heater unit is arranged between the dielectric substrate and the base plate, a gas hole is also formed in the heater unit.

During substrate processing, there is a possibility that insulation breakdown occurs along a path through gas holes between the substrate, which has become a high potential due to exposure to plasma, and the base plate and the like. In recent years, an output of plasma used for etching and the like has been increasing. Thus, in the future, it is thought that insulation breakdown can occur also between the substrate and an inner surface of the gas hole formed in the heater unit.

The present invention has been made in view of such a problem and aims at providing an electrostatic chuck that can suppress occurrence of insulation breakdown along a path through gas holes.

To solve the above-described problem, an electrostatic chuck according to the present invention includes: a dielectric substrate in which a first gas hole is formed, the dielectric substrate having a placement surface on which an object to be adsorbed is placed; a heater unit that is joined to a surface on a side opposite to the placement surface in the dielectric substrate and has a second gas hole formed at a position corresponding to the first gas hole; a base plate that is joined to a surface on a side opposite to the dielectric substrate in the heater unit and has a third gas hole formed at a position corresponding to the second gas hole; and an air-permeable member that is made of an insulator and has air permeability, the air-permeable member being arranged so as to enter both an interior of the second gas hole and an interior of the third gas hole.

In the electrostatic chuck having such a configuration, an insulation breakdown path that extends from a substrate under processing and reaches an inner surface of the second gas hole through the first gas hole can be physically blocked by the air-permeable member. Accordingly, occurrence of insulation breakdown along a path through the gas holes is suppressed.

According to the present invention, it is possible to provide an electrostatic chuck that can suppress occurrence of insulation breakdown along a path through gas holes.

### BRIEF DESCRIPTION OF THE DRAWINGS

FIG. 1 is a cross-sectional view schematically illustrating a configuration of an electrostatic chuck according to a first embodiment;

FIG. 2 is an exploded view schematically illustrating a configuration of a heater unit;

FIG. 3 is a diagram illustrating an example of arrangement of sub-heater layers in the heater unit;

FIG. 4 is a diagram illustrating a configuration of one sub-heater layer;

FIG. 5 is a diagram illustrating an example of arrangement of main heater layers in the heater unit;

FIG. 6 is a diagram illustrating a configuration of one main heater layer;

FIG. 7 is a diagram for explaining a role of a bypass layer and the like;

FIG. 8 is an expanded cross-sectional view illustrating a configuration of a part of the electrostatic chuck according to the first embodiment;

FIG. 9 is an expanded cross-sectional view illustrating a configuration of a part of an electrostatic chuck according to a second embodiment;

FIG. 10 is an expanded cross-sectional view illustrating a configuration of a part of an electrostatic chuck according to a third embodiment; and

FIG. 11 is an expanded cross-sectional view illustrating a configuration of a part of an electrostatic chuck according to a comparative example.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

A first embodiment will be described. An electrostatic chuck 10 according to the present embodiment is configured to adsorb and hold a wafer W set as a process target by an electrostatic force inside a semiconductor manufacturing apparatus such as, for example, an etching apparatus which is not illustrated in the drawing. The wafer W that is an object to be adsorbed is, for example, a silicon wafer. The electrostatic chuck 10 may be used in an apparatus other than the semiconductor manufacturing apparatus.

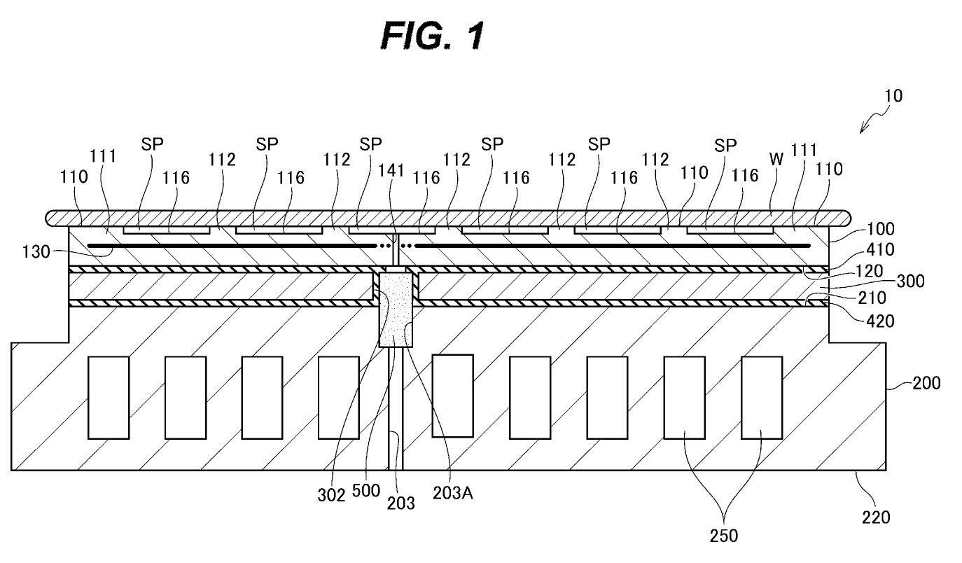

FIG. 1 is a cross-sectional view schematically illustrating a configuration of the electrostatic chuck 10 in a state in which the wafer W is attracted and held. The electrostatic chuck 10 includes a dielectric substrate 100, a base plate 200, and a heater unit 300.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a "placement surface" on which the wafer W is placed. A surface 120 on a lower side (that is, a side opposite to the placement surface) in FIG. 1 in the dielectric substrate 100 serves as a "surface to be joined" which is joined to the heater unit 300 through a joining layer 410. A perspective in a case where the electrostatic chuck 10 is viewed from the surface 110 side along a direction perpendicular to the surface 110 will also be hereinafter expressed as "top view".

An attraction electrode 130 is embedded inside the dielectric substrate 100. The attraction electrode 130 is a thin planar (plate-like) layer made of a metallic material such as, for example, tungsten, and is arranged so as to be parallel to the surface 110. As a material of the attraction electrode 130, molybdenum, platinum, palladium, and the like may be used in addition to tungsten. When a voltage is applied to the attraction electrode 130 from an outside via a feed line which is not illustrated in the drawing, an electrostatic force is generated between the surface 110 and the wafer W, and according to this, the wafer W is adsorbed and held. As a configuration of the above-described feed line, various configurations in related art can be adopted. The single attraction electrode 130 may be provided as so-called a "monopolar" electrode as in the present embodiment, but may also include two attraction electrodes as so-called "bipolar" electrodes.

As illustrated in FIG. 1, a space SP is formed between the dielectric substrate 100 and the wafer W. When a process such as etching is performed in the semiconductor manufacturing apparatus, a helium gas for temperature regulation is supplied to the space SP from the outside via the first gas hole 141 which will be described later. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is a wall which defines the space SP in a position corresponding to an outermost circumference. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the processing can be set to be close to uniformity.

A part denoted by reference sign "116" in FIG. 1 is a bottom of the space SP. Hereinafter, this part may also be referred to as a "bottom 116". The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The first gas hole 141 is formed in the dielectric substrate 100. The first gas hole 141 is a hole for supplying helium gas to the space SP, and is a circular through hole formed so as to extend vertically with respect to the surface 110. The first gas hole 141 includes a plurality of first gas holes 141, but FIG. 1 illustrates only one of the first gas holes 141. Helium gas supplied from outside sequentially passes through a third gas hole 203 formed in the base plate 200 and a second gas hole 302 formed in the heater unit 300, and is then supplied to the space SP through the first gas hole 141.

For example, a porous body made of alumina or the like may be arranged inside the first gas hole 141. With such a configuration, while flow of the gas in the first gas hole 141 is secured, occurrence of insulation breakdown in a path through the first gas hole 141 can be suppressed.

The base plate 200 is a substantially disk-shaped member that supports the dielectric substrate 100 and the heater unit 300. The base plate 200 is made of, for example, a metallic material such as aluminum. A surface 210 on the upper side in FIG. 1 in the base plate 200 serves as a "surface to be joined" which is joined to the heater unit 300 via a joining layer 420. The base plate 200 is joined to a surface on a side opposite to the dielectric substrate 100 side in the heater unit 300.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200.

In the base plate 200, the third gas hole 203 is formed at each position corresponding to the first gas hole 141 and the second gas hole 302 to be described later. The "position corresponding to the second gas hole 302" is a position overlapping the second gas hole 302 in top view. The third gas hole 203 is a circular through hole formed so as to vertically extend from the surface 210 toward the surface 220. A central axis of the third gas hole 203 matches a central axis of the first gas hole 141. As described above, the first gas hole 141 serves as a part of a path for supplying helium gas to the space SP.

The third gas hole 203 may be formed so as to extend entirely in a linear shape as in the present embodiment, or may be formed so as to bend on a way from the surface 210 toward the surface 220. The plurality of third gas holes 203 on the surface 210 side may be aggregated into a small number of flow paths inside the base plate 200, and the flow paths may be extended to the surface 220 side.

An insulating film may be formed on a surface of the base plate 200. As the insulating film, for example, an alumina film formed by thermal spraying can be used. When the surface of the base plate 200 is covered by the insulating film, it is possible to increase an insulation withstand voltage of the base plate 200.

The heater unit 300 generates heat by receiving power supplied from the outside, and heats the dielectric substrate 100. As described later, the heater unit 300 includes a plurality of heat generation portions 331 and the like, and a heating value at each heat generation portion 331 and the like can be individually regulated. By individually regulating the heating value at each component, the in-plane temperature distribution of the wafer W during processing can be made closer to uniform.

The heater unit 300 is sandwiched between the dielectric substrate 100 and the base plate 200, and joined to each of them. The heater unit 300 is joined to the dielectric substrate 100 via the joining layer 410, and the heater unit 300 is joined to the base plate 200 via the joining layer 420. Each of the joining layers 410 and 420 is a layer formed by curing a silicone adhesive, for example. In an inner part of each of the joining layers 410 and 420, a plurality of particulate fillers for enhancing thermal conductivity are arranged. As the filler, for example, particles containing alumina as a principal component can be used.

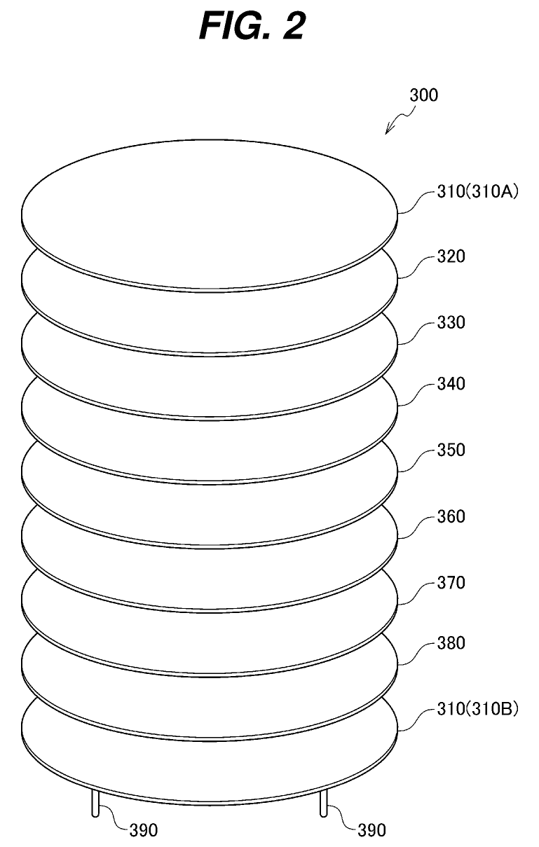

A specific configuration of the heater unit 300 will be described. FIG. 2 illustrates a configuration of the heater unit 300 as a schematic exploded view. As illustrated in FIG. 2, the heater unit 300 includes a support plate 310 (310A), an insulating layer 320, a sub-heater layer 330, an insulating layer 340, a main heater layer 350, an insulating layer 360, a bypass layer 370, an insulating layer 380, a support plate 310 (310B), and a power supply terminal 390. In the present embodiment, the sub-heater layer 330, the main heater layer 350, and the bypass layer 370 are arranged in the stated order from top in FIG. 2, but their arrangement order may be different from that in the present embodiment.

The support plate 310 is a substantially disk-shaped member, and provided at each of end parts on upper and lower sides in FIG. 2 of the heater unit 300. The support plate 310 provided at the end part on the upper side in FIG. 2 will also be hereinafter referred to as a "support plate 310A". The support plate 310 provided at the end part on the lower side in FIG. 2 will also be hereinafter referred to as a "support plate 310B". The support plate 310A is a portion joined to the surface 120 of the dielectric substrate 100 via the joining layer 410, and the support plate 310B is a portion joined to the surface 210 of the base plate 200 via the joining layer 420.

A pair of the support plates 310A and 310B are members for reinforcing the whole heater unit 300 by sandwiching the whole of the sub-heater layer 330, the main heater layer 350, the bypass layer 370, and the like therebetween. In the present embodiment, both of the support plates 310A and 310B are made of metal, but may be made of another member (for example, an insulating member). In each member such as the support plate 310 constituting the heater unit 300, a through hole for allowing a lift pin to pass, a through hole (the second gas hole 302 to be described later) for allowing helium gas to pass, and the like are formed, but these through holes are not illustrated in FIG. 2.

The insulating layer 320 is a layer provided between the support plate 310A and the sub-heater layer 330 to electrically insulate therebetween. The insulating layer 320 also has a role of physically joining the support plate 310A with the sub-heater layer 330. The insulating layer 320 is a polyimide film in the present embodiment, but may contain components other than polyimide, and may be made of a material different from polyimide. In a case in which the support plate 310A is made of an insulating material, the insulating layer 320 can be eliminated.

The sub-heater layer 330 is a portion that generates heat by receiving power supplied from the outside. In FIG. 2, the sub-heater layer 330 is schematically illustrated as a single disk, but the sub-heater layer 330 is actually divided into a plurality of regions, and each of the regions can be caused to individually generate heat. A specific configuration of the sub-heater layer 330 will be described later.

The insulating layer 340 is a layer provided between the sub-heater layer 330 and the main heater layer 350 to electrically insulate therebetween. The insulating layer 340 also has a role of physically joining the sub-heater layer 330 with the main heater layer 350. The insulating layer 340 is a polyimide film in the present embodiment, but may contain components other than polyimide, and may be made of a material different from polyimide.

Similarly to the sub-heater layer 330 described above, the main heater layer 350 is a portion that generates heat by receiving power supplied from the outside. In FIG. 2, the main heater layer 350 is schematically illustrated as a single disk, but the main heater layer 350 is actually divided into a plurality of regions, and each of the regions can be caused to individually generate heat. A specific configuration of the main heater layer 350 will be described later.

A heating value per unit area of the main heater layer 350 is larger than that of the sub-heater layer 330 described above. The main heater layer 350 is used for rising a temperature of the whole dielectric substrate 100 in a short time. The sub-heater layer 330 is used for regulating a temperature of each component of the dielectric substrate 100, and making the in-plane temperature distribution of the wafer W approximately uniform. In this way, in the present embodiment, the two heater layers having respective roles are individually provided.

The insulating layer 360 is a layer provided between the main heater layer 350 and the bypass layer 370 to electrically insulate therebetween. The insulating layer 360 also has a role of physically joining the main heater layer 350 with the bypass layer 370. The insulating layer 360 is a polyimide film in the present embodiment, but may contain components other than polyimide, and may be made of a material different from polyimide.

The bypass layer 370 is a layer for electrically connecting the power supply terminal 390 to be described later with the sub-heater layer 330 and the main heater layer 350. In FIG. 2, the bypass layer 370 is schematically illustrated as a single disk, but the bypass layer 370 is actually divided into a plurality of parts. By providing the bypass layer 370 in a middle of an electric circuit connected to the sub-heater layer 330 and the like, it is possible to regulate a position of the power supply terminal 390 and the like. Each of the divided parts of the bypass layer 370 is partially electrically connected to the sub-heater layer 330 or the main heater layer 350.

The insulating layer 380 is a layer provided between the bypass layer 370 and the support plate 310B to electrically insulate therebetween. The insulating layer 380 has also a role of physically joining the bypass layer 370 with the support plate 310B. The insulating layer 380 is a polyimide film in the present embodiment, but may contain components other than polyimide, and may be made of a material different from polyimide. In a case in which the support plate 310B is made of an insulating material, the insulating layer 380 can be eliminated.

At the time of manufacturing the heater unit 300, the respective layers illustrated in FIG. 2 are pressurized and heated as a whole in a laminated state. Due to this, the whole layers are joined and integrated with each other via the insulating layer 320 that is a polyimide film and the like.

The power supply terminal 390 is a portion that receives power required for causing the sub-heater layer 330 and the like to generate heat from the outside. In the present embodiment, the power supply terminal 390 is formed as an elongated bar-shaped plug, and has one end part joined to the bypass layer 370. The power supply terminal 390 includes a plurality of power supply terminals 390 in accordance with the number of the bypass layers 370, only two of them are illustrated in FIG. 2. A non-illustrated through hole is formed at each position corresponding to the power supply terminal 390 in the base plate 200, and the power supply terminal 390 is inserted through the through hole.

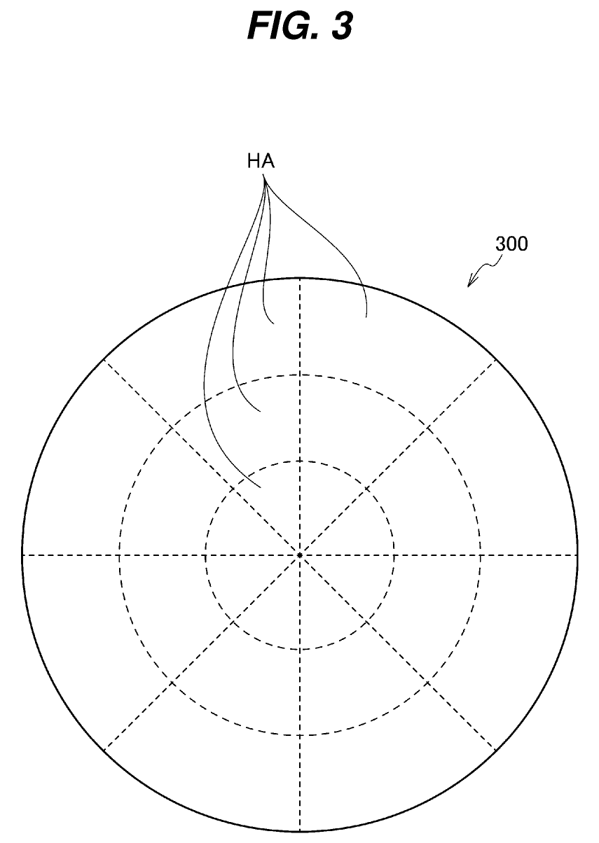

A configuration of the sub-heater layer 330 will be described. As described above, the sub-heater layer 330 is divided into the plurality of regions, and heat can be individually generated in each of the regions. FIG. 3 illustrates an example of a manner of dividing the sub-heater layer 330 in top view. In this example, the sub-heater layer 330 is divided into twenty-four regions HA in total.

The sub-heater layer 330 is configured as the linear heat generation portion 331, and individually routed in each of the regions HA. That is, twenty-four heat generation portions 331 in total are provided in the present embodiment.

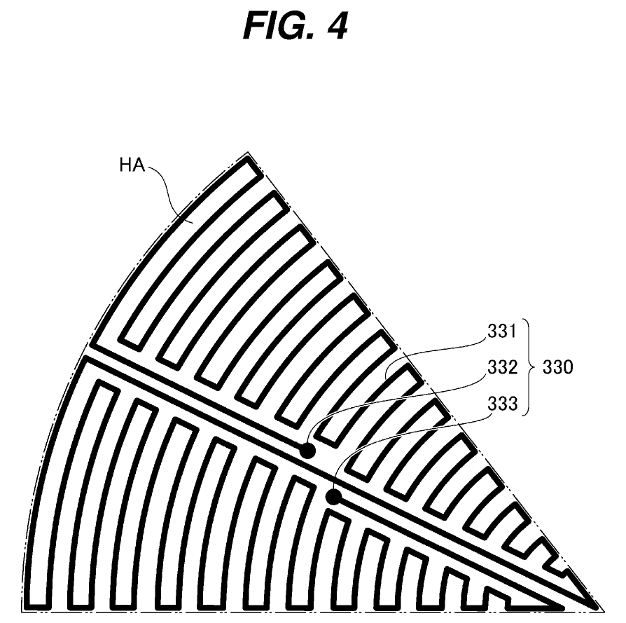

FIG. 4 illustrates an example of the heat generation portion 331 routed in one region HA. In each of the regions HA, the one linear heat generation portion 331 is routed along a path uniformly passing through substantially the entire range thereof. The heat generation portion 331 is a portion that generates heat by receiving power supplied from the outside.

At both ends of the heat generation portion 331, circular pad parts 332 and 333 are respectively formed. The heat generation portion 331 and the pad parts 332 and 333 are formed by performing etching on thin metal foil, for example, and the whole thereof functions as one sub-heater layer 330. In other words, one sub-heater layer 330 is provided for each of the twenty-four regions HA in total.

A shape of the heat generation portion 331 illustrated in FIG. 4 is schematic, and is different from a real shape. The same applies to positions of the pad parts 332 and 333.

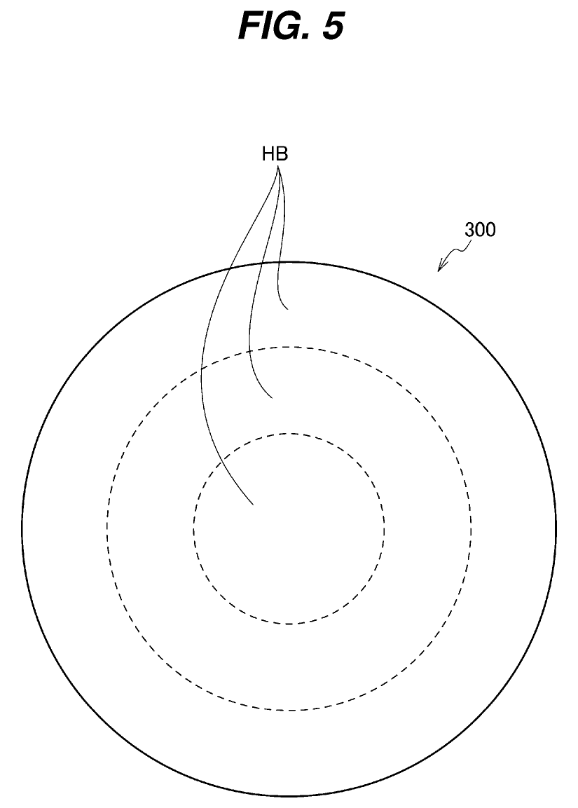

A configuration of the main heater layer 350 will be described. Similarly to the sub-heater layer 330, the main heater layer 350 is also divided into a plurality of regions, and each of the regions can be caused to individually generate heat. FIG. 5 illustrates an example of a manner of dividing the main heater layer 350 in top view. In this example, the main heater layer 350 is divided into three regions HB in total.

The main heater layer 350 is configured as a linear heat generation portion 351, and individually routed in each of the regions HB. That is, the three heat generation portions 351 in total are provided in the present embodiment.

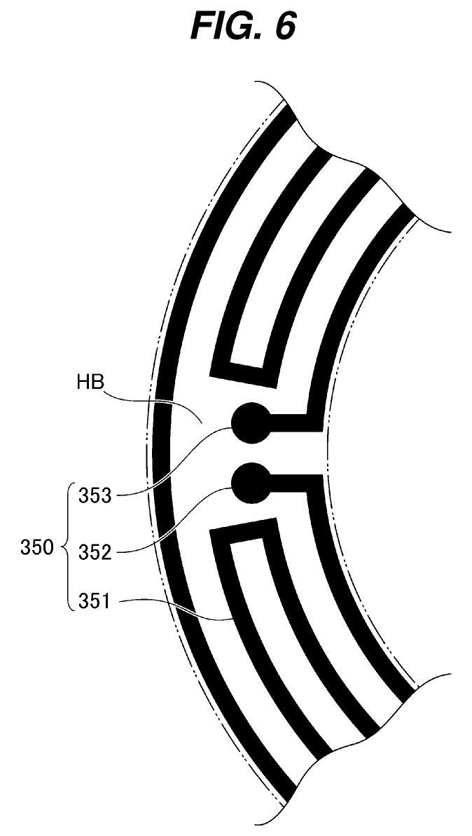

FIG. 6 illustrates an example of the heat generation portion 351 routed in one region HB. In each of the regions HB, the one linear heat generation portion 351 is routed along a path uniformly passing through substantially the entire range. The heat generation portion 351 is a portion that generates heat by receiving power supplied from the outside. The number of the heat generation portions 351 (three in total) is less than the number of the heat generation portions 331 (twenty-four in total).

At both ends of the heat generation portion 351, circular pad parts 352 and 353 are respectively formed. The heat generation portion 351 and the pad parts 352 and 353 are formed by performing etching on thin metal foil, for example, and the whole thereof functions as one main heater layer 350. In other words, one main heater layer 350 is provided for each of the three regions HB in total.

A shape of the heat generation portion 351 illustrated in FIG. 6 is schematic, and is different from a real shape. The same applies to positions of the pad parts 352 and 353.

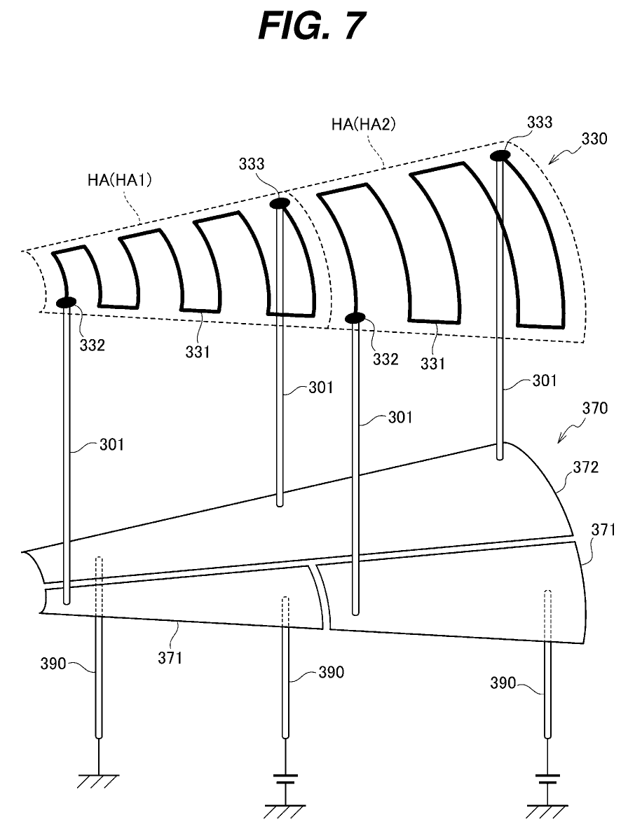

FIG. 7 illustrates a schematic perspective view of a configuration including two of the regions HA, the two sub-heater layers 330 arranged in them, the bypass layer 370 connected to the sub-heater layers 330, and the like. One of the two regions HA illustrated in FIG. 7 will also be hereinafter referred to as a "region HA1". The other region HA will also be hereinafter referred to as a "region HA2". Shapes of the heat generation portions 331 and the like illustrated in FIG. 7 are schematic, and are different from real shapes.

As described above, the bypass layer 370 is divided into the plurality of parts. FIG. 7 illustrates only three of the plurality of divided parts of the bypass layer 370. Each of the three divided parts of the bypass layer 370 denoted by reference sign "371" in FIG. 7 is arranged at a position overlapped with only one of the regions HA in top view. That is, it is individually arranged at a position immediately below each of the regions HA. A portion of the bypass layer 370 that is arranged as described above will also be hereinafter referred to as a "bypass layer 371".

Each of the divided parts of the bypass layer 370 denoted by reference sign "372" in FIG. 7 is arranged at a position overlapped with both of the region HA1 and the region HA2 in top view. A portion of the bypass layer 370 that is arranged as described above will also be hereinafter referred to as a "bypass layer 372".

In the sub-heater layer 330 arranged in the region HA1, the pad part 332 at one end of the heat generation portion 331 is electrically connected to the bypass layer 371 immediately below the pad part 332. The pad part 333 at the other end of the heat generation portion 331 is electrically connected to the bypass layer 372.

Similarly to the above, in the sub-heater layer 330 arranged in the region HA2, the pad part 332 at one end of the heat generation portion 331 is electrically connected to the bypass layer 371 immediately below the pad part 332. The pad part 333 at the other end of the heat generation portion 331 is electrically connected to the bypass layer 372.

The electrical connection between the respective parts as described above are implemented by welding upper and lower layers to each other, for example. For ease of understanding of the configuration, in FIG. 7, each welding part is schematically illustrated as a stick-shaped member extending in a straight line (a portion denoted by reference sign 301). At a portion overlapped with each welding part in top view, an opening is formed in each of layers (the insulating layer 340, the main heater layer 350, and the insulating layer 360) between the sub-heater layer 330 and the bypass layer 370, and the sub-heater layer 330 and the bypass layer 370 are directly connected through the opening.

The sub-heater layer 330 and the bypass layer 370 may be electrically connected by welding as in the present embodiment, but may be electrically connected by using another method. For example, they may be electrically connected via a conductive member extending in an upper and lower direction. In any configuration, the sub-heater layer 330 and the bypass layer 370 are connected via an electric circuit denoted by reference sign 301 in FIG. 7. The electric circuit will also be hereinafter referred to as a "connection part 301".

One end of the power supply terminal 390 is joined to each of the bypass layers 371 from the lower side in FIG. 7. A voltage is individually applied to each of the power supply terminals 390 from an external DC power supply. One end of the power supply terminal 390 is also joined to the bypass layer 372 from the lower side in FIG. 7. The power supply terminal 390 is grounded.

As described above, in each of the sub-heater layers 330 provided for each of the regions HA, the one pad part 332 is connected to the individual DC power supply via the bypass layer 371, and the other pad part 333 is grounded via the common bypass layer 372. The other sub-heater layers 330 not illustrated in FIG. 7 are also connected to the DC power supply and the like with the same configuration. With such a configuration, it is possible to individually supply power to each of the plurality of sub-heater layers 330, and regulate a heating value at each part.

It is also possible to supply power directly from the power supply terminal 390 without using the bypass layer 370 to the sub-heater layer 330. However, with the configuration of supplying power via the bypass layer 370 as in the present embodiment, a degree of freedom in arrangement of the power supply terminal 390 can be enhanced, or the power supply terminals 390 to be grounded can be integrated into one terminal.

Power supply to each of the main heater layers 350 is implemented by the same configuration as described above. Its specific configuration is the same as in FIG. 7, and thus description and illustration thereof are omitted.

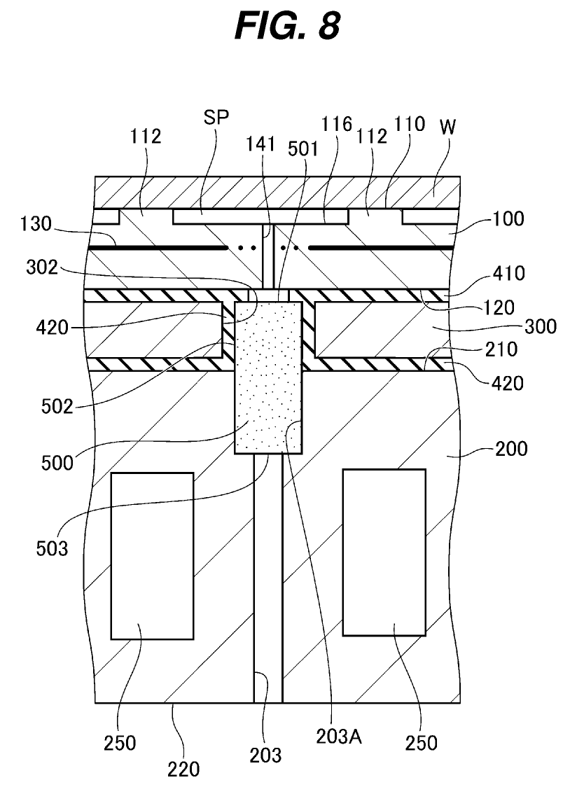

A specific configuration of the path for supplying helium gas to the space SP will be described. FIG. 8 illustrates an enlarged view of a configuration of neighboring parts of the first gas hole 141, the second gas hole 302, and the third gas hole 203 in the electrostatic chuck 10 illustrated in FIG. 1.

The second gas hole 302 is formed at each position corresponding to the first gas hole 141 in the heater unit 300. The "position corresponding to the first gas hole 141" is a position overlapped with the first gas hole 141 in top view. The second gas hole 302 is a circular through hole formed so as to vertically extend from the dielectric substrate 100 side toward the base plate 200 side. A central axis of the second gas hole 302 matches central axes of the first gas hole 141 and the third gas hole 203. As described above, the second gas hole 302 serves as a part of the path for supplying helium gas to the space SP.

An inner diameter of the second gas hole 302 is larger than an inner diameter of the first gas hole 141. Although not illustrated in FIG. 8, any of conductor layers such as the heat generation portion 331, the heat generation portion 351, and the bypass layer 370 provided inside the heater unit 300 is not exposed at an inner surface of the second gas hole 302. Only the support plate 310 and the insulating layers 320, 340, 360, and 380 are exposed at the inner surface of the second gas hole 302.

At a neighboring part of the surface 210 in the base plate 200, the third gas hole 203 is enlarged in diameter. In the third gas hole 203, a portion enlarged in diameter in this way will also be hereinafter referred to as an "enlarged part 203A". An inner diameter of the enlarged part 203A is slightly smaller than the inner diameter of the second gas hole 302.

An air-permeable member 500 is arranged inside the enlarged part 203A in the third gas hole 203. The air-permeable member 500 is a cylindrical member, and the whole thereof is made of a porous ceramic material. That is, the air-permeable member 500 is a member that is made of an insulator and has air permeability. An insulating material different from a ceramic material may be used as a material of the air-permeable member 500. A porosity of the air-permeable member 500 is appropriately set in accordance with a balance between air permeability required for supplying gas to the space SP and a necessary insulation withstand voltage.

An outer diameter of the air-permeable member 500 is substantially equal to the inner diameter of the enlarged part 203A. Accordingly, no gap is formed between an outer surface 502 of the air-permeable member 500 and an inner surface of the enlarged part 203A. An adhesive or the like may be interposed so as to fill a minute gap therebetween. A lower end 503 of the air-permeable member 500 is in contact with a stepped portion at a lower end of the enlarged part 203A. Accordingly, the whole internal space of the enlarged part 203A is filled with the air-permeable member 500.

The air-permeable member 500 is arranged such that its lower portion enters an interior of the third gas hole 203 (the enlarged part 203A) and its upper portion enters an interior of the second gas hole 302. An upper end 501 of the air-permeable member 500 is on the upper side relative to the surface 210 of the base plate 200, and is at a height position substantially equal to an upper end of the heater unit 300. A minute gap is formed between the upper end 501 of the air-permeable member 500 and the surface 120 of the dielectric substrate 100.

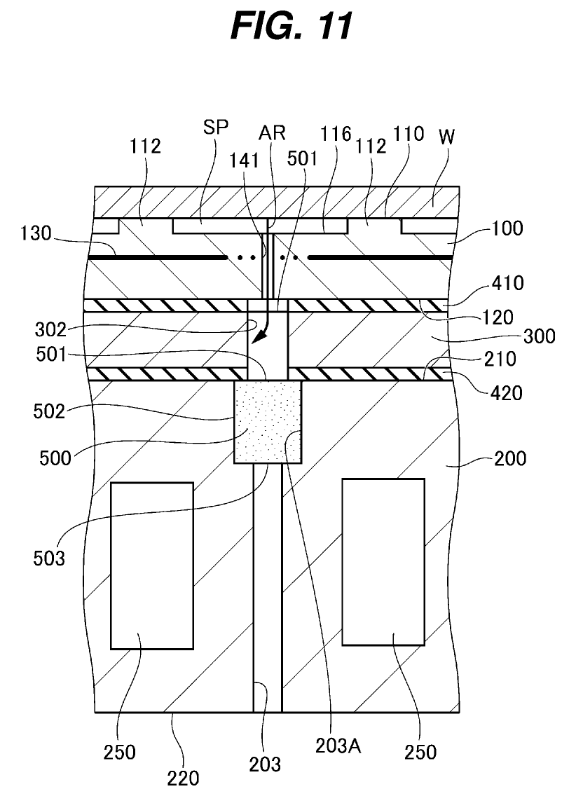

In order to clarify advantages of adopting such a configuration, a comparative example of the present embodiment will first be described. In the comparative example with a configuration illustrated in FIG. 11, the air-permeable member 500 does not enter the interior of the second gas hole 302. The upper end 501 of the air-permeable member 500 is at a height position substantially equal to the surface 210.

During substrate processing in the semiconductor manufacturing apparatus, there is a possibility that insulation breakdown occurs along a path through the first gas hole 141 and the like between the wafer W, which has become a high potential due to exposure to plasma, and the base plate 200 and the like. However, even in the configuration of the comparative example illustrated in FIG. 11, insulation breakdown along such a path can be prevented to some extent by arranging the air-permeable member 500.

In recent years, an output of plasma used for etching and the like has been increasing. Thus, in the future semiconductor manufacturing apparatuses, it is thought that insulation breakdown can occur along a path as illustrated with arrow AR in FIG. 11 also between the wafer W and the inner surface of the second gas hole 302. Specifically, it is thought that insulation breakdown can occur along a path that extends from the wafer W and reaches a conductor portion (for example, the heat generation portion 331) provided inside the heater unit 300.

Thus, in the electrostatic chuck 10 according to the present embodiment, as illustrated in FIG. 8, the air-permeable member 500 is arranged so as to enter both of the interior of the second gas hole 302 and the interior of the third gas hole 203. In such a configuration, an insulation breakdown path (path illustrated with arrow AR in FIG. 11) that extends from the wafer W under processing and reaches the inner surface of the second gas hole 302 through the first gas hole 141 can be physically blocked by the air-permeable member 500. Accordingly, occurrence of insulation breakdown along a path through the first gas hole 141 and the like can be suppressed.

As illustrated in FIG. 8, a gap is formed between an inner peripheral surface of the second gas hole 302 and the outer surface 502 of the air-permeable member 500. A part of the joining layer 420 that connects the heater unit 300 and the base plate 200 also enters the gap and is connected to the joining layer 410 on the upper side. Accordingly, the whole gap between the inner peripheral surface of the second gas hole 302 and the outer surface 502 of the air-permeable member 500 is filled with the joining layer 420. In such a configuration, the insulation breakdown path as illustrated with arrow AR in FIG. 11 is blocked by both of the air-permeable member 500 and the joining layer 420, and thus insulation breakdown can be further suppressed. Instead, a part of the joining layer 410 that connects the heater unit 300 and the dielectric substrate 100 may enter between the inner peripheral surface of the second gas hole 302 and the outer surface 502 of the air-permeable member 500.

As described above, a minute gap is formed between the upper end 501 of the air-permeable member 500 and the surface 120 of the dielectric substrate 100.

According to Paschen's law, the pressure of helium gas inside the first gas hole 141 and the like is often in a pressure range in which insulation breakdown becomes more likely to occur as a space becomes larger. Thus, the size of the above-described gap (distance between the upper end 501 and the surface 120) is preferably equal to or smaller than 0.5 mm. In this way, by bringing the upper end 501 of the air-permeable member 500 sufficiently close to the dielectric substrate 100, insulation breakdown can be further suppressed.

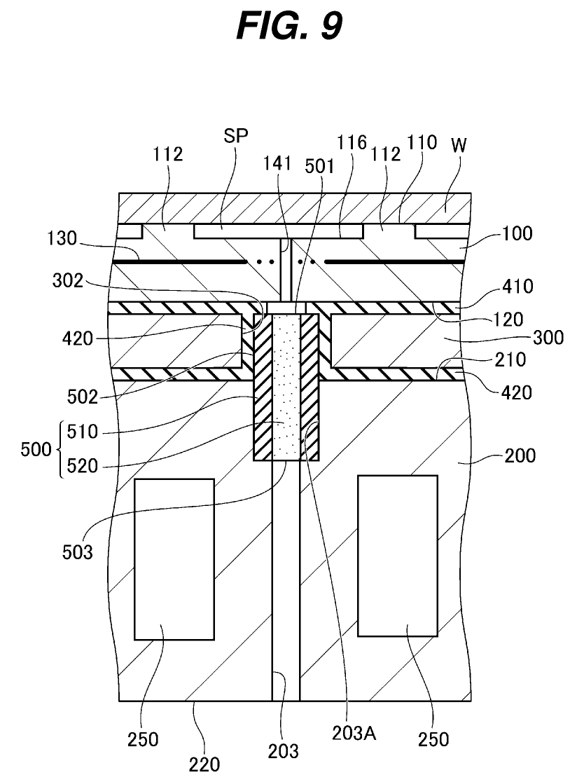

A second embodiment will be described with reference to FIG. 9. In the following, features different from those of the first embodiment will be mainly described, and description of features common to those of the first embodiment is omitted as appropriate. The present embodiment is different from the first embodiment in the configuration of the air-permeable member 500.

An outer shape of the air-permeable member 500 in the present embodiment is the same as an outer shape of the air-permeable member 500 in the first embodiment. However, the air-permeable member 500 of the present embodiment includes a dense portion 510 and a porous portion 520, and these portions are integrated.

The dense portion 510 is a portion made of dense ceramic that does not have air permeability. The dense portion 510 has a cylindrical shape, and the porous portion 520 is housed therein. The porous portion 520 is a portion made of porous ceramic that has air permeability. The porous portion 520 has a cylinder shape. A length of the porous portion 520 in a direction vertical to the placement surface is equal to a length of the dense portion 510 in the same direction. Helium gas to be supplied to the space SP passes through only the porous portion 520 of the air-permeable member 500. A porosity of the porous portion 520 is appropriately set in accordance with the balance between air permeability required for supplying gas to the space SP and a necessary insulation withstand voltage.

A ceramic material (in the present embodiment, alumina) constituting the porous portion 520 is the same as a ceramic material constituting the dense portion 510. As an alternative to such an aspect, the portions may be made of materials different from each other. The dense portion 510 and the porous portion 520 may be formed by joining and integrating separate members that are separable from each other, but they may be integrated from the beginning by sintering. With the configuration as described above, an effect similar to that described in the first embodiment can also be attained.

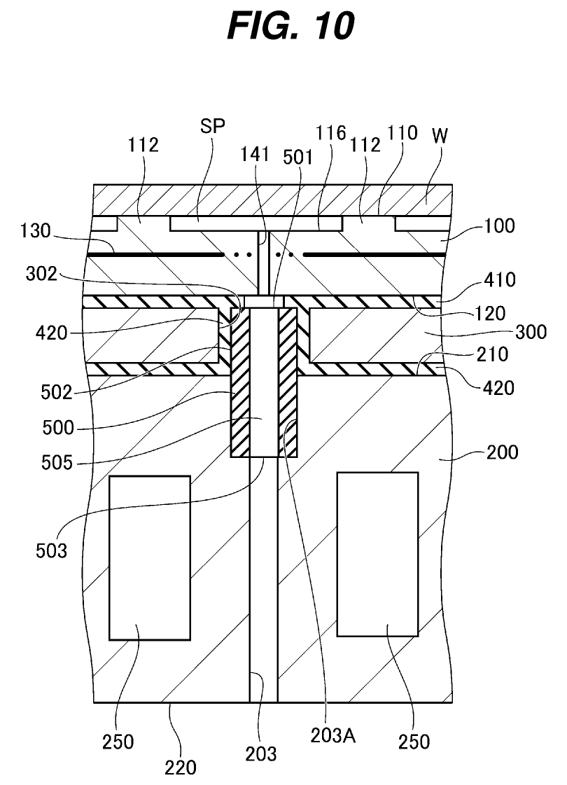

A third embodiment will be described with reference to FIG. 10. In the following, features different from those of the first embodiment will be mainly described, and description of features common to those of the first embodiment is omitted as appropriate. The present embodiment is also different from the first embodiment in the configuration of the air-permeable member 500.

The air-permeable member 500 in the present embodiment has a cylindrical shape as a whole. The shape of the air-permeable member 500 is the same as the shape of the dense portion 510 in the second embodiment. That is, the air-permeable member 500 of the present embodiment has a configuration in which the inner porous portion 520 is omitted from the air-permeable member 500 in the second embodiment (FIG. 9). A flow path 505 that extends from the base plate 200 side toward the dielectric substrate 100 side is formed inside the air-permeable member 500. Helium gas to be supplied to the space SP passes through the flow path 505 of the air-permeable member 500. With the configuration as described above, an effect similar to that described in the first embodiment can also be attained.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate in which a first gas hole is formed, the dielectric substrate having a placement surface on which an object to be adsorbed is placed;
a heater unit that is joined to a surface of the dielectric substrate on a side opposite to the placement surface and has a second gas hole formed at a position corresponding to the first gas hole;
a base plate that is joined to a surface of the heater unit on a side opposite to the dielectric substrate and has a third gas hole formed at a position corresponding to the second gas hole; and
an air-permeable member that is made of an insulator and has air permeability, the air-permeable member being arranged so as to enter both an interior of the second gas hole and an interior of the third gas hole.

2. The electrostatic chuck according to claim 1, wherein the air-permeable member is made of a porous material.

3. The electrostatic chuck according to claim 1, wherein a joining layer that connects the heater unit and the base plate or a joining layer that connects the heater unit and the dielectric substrate enters between an inner surface of the second gas hole and the air-permeable member.

4. The electrostatic chuck according to claim 1, wherein a distance between the air-permeable member and the dielectric substrate is equal to or smaller than 0.5 mm.
